(19) United States
(12) Patent Application Publication
(10) Pub. No.: US 2007/0236275 A1
(43) Pub. Date: Oct. 11, 2007

(54) Global Reference Voltage Distribution System With Local Reference Voltages Referred to Ground And Supply

(75) Inventors: Yossi Smeloy, Mitzpe Kamon (IL); Ronen Eckhouse, Shimshit (IL)

Correspondence Address: DR. MARK M. FRIEDMAN;C/O BILL POLKINGHORN - DISCOVERY DISPATCH, 9003 FLORIN WAY, UPPER MARLBORO, MD, 20772, US

(73) Assignee: MELLANOX TECHNOLOGIES LTD., Yokneam (IL)

(21) Appl. No.: 11/691,513

(22) Filed: Mar. 27, 2007

Related U.S. Application Data
(60) Provisional application No. 60/789,875, filed on Apr. 7, 2006.

(51) Int. Cl. G11C 5/14

(52) U.S. Cl. 327/530

(57) ABSTRACT

A system and method for distributing a reference voltage in a system such as an integrated circuit wherein a master reference voltage is distributed via a differential pair of conductors Local reference voltage generators produce local reference voltages proportional to the master reference voltage, but referred to local ground and/or a local power supply voltage.

This is a continuation-in-part of U.S. Provisional Patent Application No. 60/789,875, filed Apr. 7, 2006

### FIELD AND BACKGROUND OF THE INVENTION

The present invention relates to a system and method for providing a reference voltage on a system such as an integrated circuit (IC) and, more particularly, distributing this reference within the system as a difference in the voltage of a pair of conductors. Local reference voltages relative to ground and/or a power supply voltage are provided for local regions of the system by circuits operative to produce voltages proportional to the voltage difference between the pair of conductors and referenced to a local ground or power supply voltage.

Although the following discussion primarily refers to ICs, it will be readily apparent to those skilled in the art that the principles of the present invention can be applied to systems in general, and the scope of the present invention includes ICs and systems in general.

A single, central reference voltage source, derived from a stable voltage source such as a bandgap reference voltage, is frequently used in large ICs in order to save area (“real estate”) and power. Distributing this reference voltage across relatively large distances may introduce voltage errors due to ground and supply voltage differences across the chip and stray voltages that are coupled inductively and/or capacitively to the conductors used to distribute the reference voltage. The present invention distributes the reference voltage differentially across the IC and sets a local reference voltage according to this voltage difference, but referenced to a local ground or supply voltage.

Various attempts have been made to provide differential voltage references.

U.S. Pat. No. 5,821,807 to Brooks introduces a differential voltage reference circuit implemented in CMOS that provides a continuous differential voltage having good substrate and power supply noise rejection and low power consumption However, U.S. Pat. No. 5,821,807 does not explain how the differential voltage can be used to provide a local voltage referenced to local ground or a local power supply voltage

U.S. Pat. No. 4,926,138 to Castello et al. introduces a fully differential voltage source. The voltage reference is obtained from a bandgap voltage source fed with currents proportional to the temperature, in order to minimize thermal voltage variations. However, U.S. Pat. No. 4,926,138 also does not offer a solution for providing a local voltage referenced to local ground or a local power supply voltage.

There is thus a widely recognized need for, and it would be highly advantageous to have, a system and method for providing a global reference voltage for an integrated circuit, preferably based upon a bandgap voltage reference, distributing this reference voltage as a voltage difference between two conductors, and providing one or more local reference voltages based upon this differential reference voltage but referenced to local ground or a local power supply voltage.

### DEFINITIONS

As used herein, unless otherwise specified, the term “real estate” refers to surface area of an integrated circuit die.

As used herein, unless otherwise specified, the term “refer”, when applied to voltages, means the difference between a first voltage and a second voltage. For example, if a first voltage is said to be 2.0V referred to a second voltage, and the second voltage is 0.1V above earth ground, the first voltage is 2.1V above earth ground.

Unless otherwise indicated, resistance values are given in ohms. “k” indicates multiplication by 1000. For example, “2k” indicates a resistance of 2000 ohms.

### SUMMARY OF THE INVENTION

According to the present invention there is provided a system for providing a local reference voltage, the system including a local reference voltage generator (e.g. 16a in FIG. 1) operative to generate a local reference voltage (e.g. V₇ or V₈ for example) referred to a local voltage (e.g. V₉ of FIG. 3 for V₇, or local ground for V₈, for example) and substantially proportional to a voltage difference between a first master reference voltage line (e.g. 12, V₁) and a second master reference voltage line (e.g. 14, V₂).

Preferably, in the local reference voltage generator (e.g. 16a), a first current substantially proportional to the voltage difference between the two master voltages (e.g. V₁ and V₂) passes through a first resistor (e.g. R₄ of FIG. 3), and a second current substantially proportional to a voltage difference across the first resistor (e.g. R₄) passes through a resistive network (e.g. R₅, R₆, R₇ of FIG. 3) having a first terminal (e.g. local ground or 46 of FIG. 3—either could serve as the reference) connected to said local voltage (e.g. local ground or V₉), and wherein said local reference voltage (e.g. V₈ or V₇) is present at a second terminal (e g. 20a or 18a) of said resistive network For example, in FIG. 3, a first current substantially proportional to the voltage difference between the two master voltages V₁ and V₂ passes trough resistor R₁, and a second current substantially proportional to the voltage difference across resistor R₄ passes through the resistive network including R₅, R₆ and R₇ The voltage V₇ on line 18a would then be a local reference voltage with respect to the local voltage V₉ on line 46, and the voltage V₈ on line 20a would be a second local reference voltage, this second local reference voltage being with respect to the local ground voltage 42.

Most preferably, the local reference generator (e.g. 16a) includes: (a) a second resistor (e.g. R₃ of FIG. 3); (b) a first field effect transistor (e.g. 30 of FIG. 3); (c) a second field effect transistor (e.g. 32 of FIG. 3); (d) a first negative feedback amplifier (e.g. 36 of FIG. 3) operative to drive the first field effect transistor so as to impress a voltage (e.g. V₃ of FIG. 3) substantially equal to the first master reference voltage upon a first terminal of the second resistor, and (e) a second negative feedback amplifier, (e.g. 38 of FIG. 3) operative to drive the second field effect transistor (e.g. 32) so as to impress a voltage (e.g. V₄ of FIG. 3) substantially equal to the second master reference voltage upon a second terminal of the second resistor, and wherein the first current flows through the second resistor.

Also most preferably, the local reference voltage generator includes: (a) a field effect transistor (e.g. 34 of FIG. 3); (b) a negative feedback amplifier (e.g. 40 of FIG. 3) operative to drive the field effect transistor so as to cause a current substantially proportional to the voltage difference across the first resistor (e.g. R₄) to flow through the resistive network (e.g. R₅, R₆, R₇).

Preferably, the system is implemented on an integrated circuit die (e.g. 60 of FIG. 1).

Preferably, the system further comprises at least two resistors (e.g. R₁ and R₂ of FIG. 2) configured as a voltage divider and operative to impress a voltage proportional to a primary reference voltage (e.g. V₀ of FIG. 2) upon one or both of the master reference voltage lines (e.g. 12 or 14). Most preferably, the primary reference voltage is obtained from a bandgap reference voltage source (e.g. V₀ on line 70 of FIG. 2).

According to the present invention there is provided a method for providing a local reference voltage, the method including the steps of: (a) providing a first master reference voltage line (e.g. 12); (b) providing a second master reference voltage line (e.g. 14), and (c) generating a local reference voltage (V₇ or V₈ for example) referred to a local voltage (V₉ for V₇, or local ground for V₈, for example) and substantially proportional to a voltage difference between the first master reference voltage line (e.g. 12) and the second master reference voltage line (e.g. 14).

Preferably, the generating of the local reference voltage is effected by steps including: (i) providing a first resistor (e.g. R₄); (ii) providing a resistive network (e.g. R₅, R₆, R₇) having a first terminal connected to the local voltage (e.g. local ground or V₉); (iii) causing a first current substantially proportional to the voltage difference between the two master voltages (e.g. V₁ and V₂) to pass through the first resistor (e.g. R₄), and (iv) causing a second current substantially proportional to a voltage across the first resistor to pass through the resistive network (e.g. R₅, R₆, R₇), the local reference voltage (e.g. V₈ or V₇) then being present at a second terminal (e.g. 20a or 18a, respectively) of the resistive network. For example, in FIG. 3, a first current substantially proportional to the voltage difference between the two master voltages V₁ and V₂ passes through resistor R₄, and a second current substantially proportional to the voltage difference across resistor R₄ passes through the resistive network including R₅, R₆ and R₇ The voltage V₇ on line 18a would then be a local reference voltage with respect to the local voltage V₉ on line 46, and the voltage V₈ on line 20a would be a second local reference voltage, this second local reference voltage being with respect to the local ground voltage 42.

Most preferably, the first current is caused to pass through the first resistor by steps including: (A) providing a second resistor (e.g. R₃); (B) providing a first field effect transistor (e.g. 30); (C) providing a second field effect transistor (e.g. 32); (D) providing a first negative feedback amplifier (e.g. 36) operative to drive the first field effect transistor so as to impress a voltage (e.g. V₃) substantially equal to the first master reference voltage upon a first terminal of the second resistor; and (E) providing a second negative feedback amplifier (e.g. 38) operative to drive the second field effect transistor (e.g. 32) so as to impress a voltage substantially equal to the second master reference voltage (e.g. V₄) upon a second terminal of the second resistor; so that the first current flows through the second resistor.

Also most preferably, the second current is caused to pass through the resistive network by steps including: (A) providing a field effect transistor (e.g. 34), and (B) providing a negative feedback amplifier (e.g. 40) operative to drive the field effect transistor so as to cause a current substantially proportional to the voltage difference across the first resistor (e.g. R₄) to flow through the resistive network (e.g. R₅, R₆, R₇).

Preferably, one or both master reference voltage lines are provided by steps including: (i) providing at least two resistors (e.g. R₁ and R₂) configured as a voltage divider, and (ii) using the voltage divider to impress a voltage proportional to a primary reference voltage (e.g. V₀) upon a master reference voltage line (e.g. 12 or 14). Most preferably, these steps also include the steps of: (iii) providing a bandgap reference voltage source (e.g. V₀ on line 70), and (iv) obtaining the primary reference voltage from the bandgap reference voltage source (e.g. V₀ on line 70).

### BRIEF DESCRIPTION OF THE DRAWINGS

The invention is herein described, by way of example only, with reference to the accompanying drawings, wherein:

FIG. 1 is a block diagram of a system for providing local reference voltages according to the present invention;

FIG. 2 illustrates schematically a preferred embodiment of a master voltage reference source having differential outputs, according to the present invention (component values shown in the Figure are exemplary and are in no way limiting);

FIG. 3 illustrates schematically a preferred embodiment of a local voltage reference source accepting differential inputs from a master voltage reference source, according to the present invention (component values shown in the Figure are exemplary and are in no way limiting).

### DESCRIPTION OF THE PREFERRED EMBODIMENTS

The present invention is of a system and method for providing a local reference voltage on an integrated circuit, wherein this local reference voltage is with respect to a local ground or power supply voltage and is proportional to a reference voltage distributed on the integrated circuit as a difference in voltage between two conductors.

The principles and operation of a voltage reference according to the present invention may be better understood with reference to the drawings and the accompanying description.

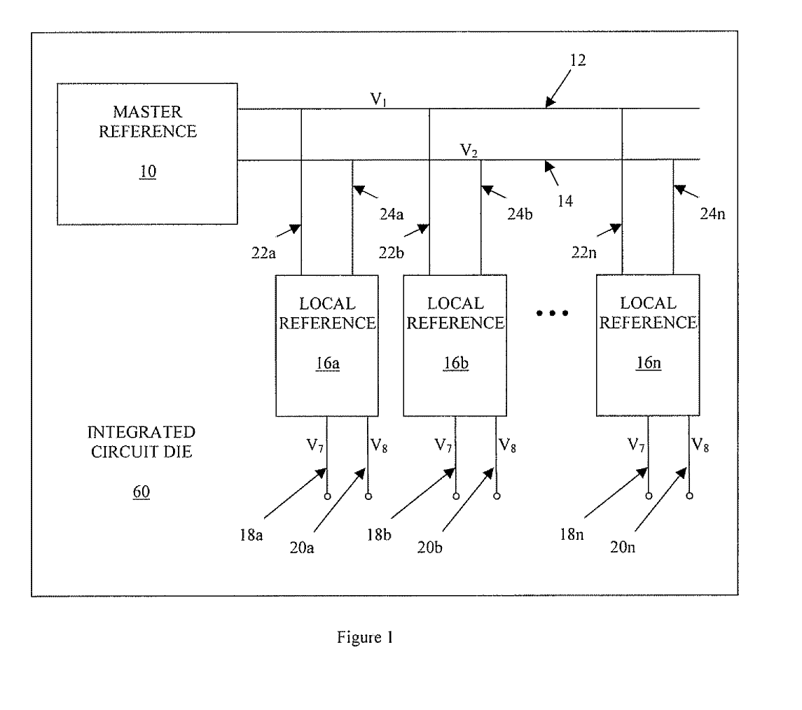

Referring now to the drawings, FIG. 1 illustrates schematically a preferred embodiment of a system for distributing a voltage reference according to the present invention. A master reference source 10 impresses a first master reference voltage V₁ on a first master reference conductor 12 and a second master reference voltage V₂ on a second master reference conductor 14. Conductors 12 and 14 each branch into respective sets of branch conductors 22a-22n and 24a-24n, which supply master reference voltages V₁ and V₂ to an arbitrary number of local reference stations 16a-16n.

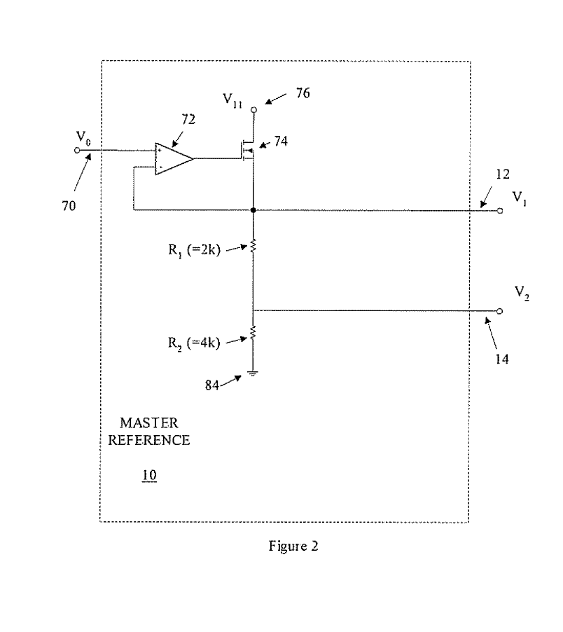

Referring now to FIG. 2, which illustrates schematically a master reference source 10 in which a differential amplifier 72 accepts a primary reference voltage V₀, provided by a reference source such as a bandgap reference (not shown), via a conductor 70 at the positive input of amplifier 72. The output of amplifier 72 drives the gate of field effect transistor (FET) 74 The drain of FET 74 is connected to a power supply terminal 76 and the source of FET 74 is connected to two series-connected resistors R₁ and R₂. The source of FET 74 is also corrected to the negative input of amplifier 72.

It will be readily apparent to those trained in the art that the above-described negative-feedback configuration of amplifier 72 causes the voltage V₁ at first master reference conductor 12 to be substantially equal to the reference voltage V₀ on conductor 70:

V₁=V₀.

It will also be readily apparent that, if the current though second master reference conductor 14 is negligibly small, the voltage V₂ at conductor 14 is substantially equal to the reference voltage V₀ on conductor 70 multiplied by the quotient of R₂ and the sum of R₁ and R₂:

V₂=V₀(R₂/(R₁+R₂)).

It will furthermore be readily apparent that the voltage difference, V₁−V₂, between conductors 12 and 14 is substantially equal to the reference voltage V₀ on conductor 70 multiplied by the quotient of R₁ and the sum of R₁ and R₂:

V₁−V₂=V₀(R₁/(R₁+R₂)).

Conductors 12 and 14 supply the differential voltage reference distribution network seen in FIG. 1.

It is preferable that pairs of conductors in the voltage reference distribution network be routed along substantially parallel pathways so that factors that alter the voltages of the conductors, such as magnetic and/or capacitive coupling, produce substantially equal disturbances in both conductors. The difference between the voltages of the conductors, which determines the local reference voltages, therefore is substantially unaffected by these factors.

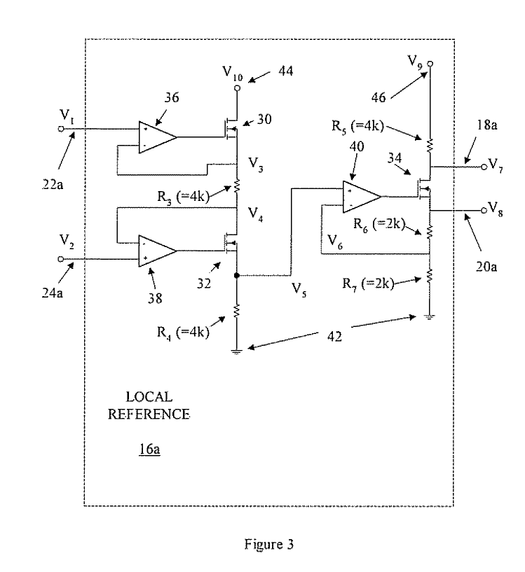

FIG. 3 illustrates schematically a local reference station 16a which, in this embodiment of the present invention, is typical of all local reference stations 16a-16n.

A branch 22a of first master reference conductor (12 in FIG. 1) is connected to the positive input of a differential amplifier 36. The output of amplifier 36 drives the gate of a FET 30. The drain of FET 30 is connected to a terminal 44 of a first local power supply and the source of FET 30 is connected to a first terminal of a resistor R₃. The source of FET 30 is also connected to the negative input of amplifier 36.

It will be readily apparent to those trained in the art that the above-described negative-feedback configuration of amplifier 36 causes the voltage V₃ at the first terminal of resistor R₃ to be substantially equal to the first master reference voltage V₁ on branch 22a:

V₃=V₁.

A branch 24a of second master reference conductor (14 in FIG. 1) is connected to the positive input of another differential amplifier 38. The output of amplifier 38 drives the gate of a FET 32. The drain of FET 32 is connected to a second terminal of resistor R₃ and the source of FET 32 is connected to a first terminal of a resistor R₄ and to the positive input of a differential amplifier 40. A second terminal of resistor R₄ is connected to a local ground 42. The drain of FET 32 is also connected to the negative input of amplifier 38.

It will be readily apparent to those trained in the art that the above-described negative-feedback configuration of amplifier 38 causes the voltage V₄ at the second terminal of resistor R₃ to be substantially equal to the second master reference voltage V₂ on branch 24a:

V₄=V₂.

It will also be readily apparent to those trained in the art that the voltage difference across resistor R₃ causes a current proportional to this voltage difference, V₃−V₄, to flow through resistor R₃.

It will be further apparent that, if the current at the negative input of amplifier 38, the current at the positive input of amplifier 40, and the gate leakage current of FET 32 are all negligible, then the current through resistor R₄ is substantially equal to the current through resistor R₃, and that the voltage V₅ at the positive input of amplifier 40 therefore is substantially equal to the voltage difference V₂−V₁ between branches 22a and 24a multiplied by the quotient of the resistances of resistors R₄ and R₃:

V₅=(V₂−V₁)(R₄/R₃).

The output of amplifier 40 drives the gate of a FET 34 The drain of FET 34 is connected to a first terminal of a resistor R₅ and to a first local reference voltage conductor 18a. A second terminal of resistor R₅ is connected to a terminal 46 of a second local power supply. The source of FET 34 is connected to a first terminal of a resistor R₆ and to a second local reference voltage conductor 20a. A second terminal of resistor R₆ is connected to a first terminal of a resistor R₇ and to the negative input of amplifier 40. A second terminal of resistor R₇ is connected to local ground 42.

It will be readily apparent to those skilled in the art that the negative-feedback configuration of amplifier 40 causes the voltage V₆ at the junction of resistors R₆ and R₇ to be substantially equal to the voltage V₅ at the positive input of amplifier 40:

V₆=V₅.

Therefore, if the current at the negative input of amplifier 40 is negligible, the voltage V₈ at second local reference voltage conductor 20a, relative to local ground 42, is substantially equal to the voltage V₆ at the junction of resistors R₆ and R₇ times the quotient of the sum of resistors R₆ and R₇ and resistor R₇:

V₈=V₆(R₆+R₇)/R₇.

Furthermore, if the input current of amplifier 40, the gate leakage of FET 34, and the currents through conductors 18a and 20a are all negligible, the current through resistor R₅ is substantially equal to the current through resistor R₇, and therefore the voltage V₇ at first local reference voltage conductor 18a is substantially equal to the voltage V₉ at terminal 46 minus the product of the voltage V₆ across resistor R₇ and the quotient of resistors R₅ and R₇:

V₇=V₉−V₆(R₅/R₇).

Thus, this preferred embodiment of the present invention provides local reference voltages referenced to a local ground and/or a local power supply voltage, and proportional to a reference voltage distributed as a differential pair.

As a non-limiting numerical example, the values of the resistors in the embodiment described above are set as follows (these values are shown in FIGS. 2 and 3):

Resistors R₁, R₆ and R₇ are each 2k.

Resistors R₂, R₃, R₄ and R₅ are each 4k.

It is to be noted that the absolute values of the individual resistors are not so important as the ratios therebetween. It is common practice, when the ratios of resistors fabricated on integrated circuits are of critical importance, to fabricate those resistors using series and/or parallel combinations of identical resistors fabricated spatially close together For example, if it is desired to have two resistors in a precise ratio of 1:2, the first resistor can be fabricated as a 5k resistor, while the second resistor can be fabricated as two 5k resistors in series, to form a 10k resistor. Preferably, all three resistors are fabricated in close spatial proximity to each other, so that the effects of variations in process parameters over the surface of the integrated circuit on the relative values of the various resistors are minimized. Accordingly, the use of series and/or parallel combinations of resistors to produce desired ratios of resistances is preferred in the implementation of the present invention. For simplicity, the use of this technique is not shown in the Figures. The production of the required resistances and resistance ratios by any technique is within the scope of the present invention.

Also, in this example, the primary reference voltage V₀ on conductor 70 is 1.2V, the voltage V₁₁ at terminal 76 is 2.0V, the voltage V₁₀ at terminal 44 is 20V, and the voltage V₉ at terminal 46 is 2.0V.

Given the above values, the voltage V₁ on conductor 12, and therefore that on branch 22a, is 12V. The voltage V₂ on branch 14, and therefore that on branch 24a, is 0.8V. The voltage V₃−V₄ across resistor R₃ is 1.2V−0.8V=0.4V and the current through resistors R₃ and R₄ is 0.4V/4k=0.1 mA. Thus, the voltage V₅, relative to local ground, at the positive input of amplifier 40, and the voltage V₆ at the junction of resistors R₆ and R₇, are both (0.1 mA)(4k)=0.4V, and the current through resistors R₅, R₆ and R₇ is 0.4V/2k=0.2 mA.

Therefore, the voltage V₇ at first local voltage reference 18a is 2.0V−((0.2 mA)(4k)), i.e., 1.2V, and the voltage V₈ at second local voltage reference 20a is (0.2 mA)(2k+2k) i.e., 0.8V. Note that V₇ is referenced to V₉, i.e. V₇ follows variations in V₉ such that V₇ is always 0.8V less than V₉. Similarly, V₈ is referenced to local ground 42, i.e. V₈ follows variations in local ground 42 such that V₈ is always 0.8V greater than local ground 42.

Note that resistors R₃ need not all have the same values in all the local reference stations 16, and similarly for the other resistors R₄ through R₇. Each local reference station's resistances are selected according to the local voltage that that local reference station is intended to supply.

While the invention has been described with respect to a limited number of embodiments, it will be appreciated that many variations, modifications and other applications of the invention may be made.

What is claimed is:

1. A system for providing a local reference voltage, the system comprising a local reference voltage generator operative to generate a local reference voltage referred to a local voltage and substantially proportional to a voltage difference between a first master reference voltage line and a second master reference voltage line.

2. The system of claim 1 wherein, in said local reference voltage generator, a first current substantially proportional to said voltage difference between said two master voltages passes though a first resistor, and wherein a second current substantially proportional to a voltage difference across said first resistor passes through a resistive network having a first terminal connected to said local voltage and wherein said local reference voltage is present at a second terminal of said resistive network.

3. The system of claim 2 wherein said local reference generator includes:
(a) a second resistor;
(b) a first field effect transistor;
(c) a second field effect transistor;
(d) a first negative feedback amplifier operative to drive said first field effect transistor so as to impress a voltage substantially equal to said first master reference voltage upon a first terminal of said second resistor, and
(e) a second negative feedback amplifier operative to drive said second field effect transistor so as to impress a voltage substantially equal to said second master reference voltage upon a second terminal of said second resistor,
and wherein said first current flows through said second resistor.

4. The system of claim 2 wherein said local reference voltage generator includes:
(a) a field effect transistor;
(b) a negative feedback amplifier operative to drive said field effect transistor so as to cause a current substantially proportional to said voltage difference across said first resistor to flow through said resistive network

5. The system of claim 1 wherein the system is implemented on an integrated circuit die.

6. The system of claim 1 wherein the system further comprises at least two resistors configured as a voltage divider and operative to impress a voltage proportional to a primary reference voltage upon a said master reference voltage line.

7. The system of claim 6 wherein said primary reference voltage is obtained from a bandgap reference voltage source.

8. A method for providing a local reference voltage, the method comprising the steps of:
(a) providing a first master reference voltage line;
(b) providing a second master reference voltage line, and
(c) generating a local reference voltage referred to a local voltage and substantially proportional to a voltage difference between said first master reference voltage line and said second master reference voltage line.

9. The method of claim 8, wherein said generating of said local reference voltage is effected by steps including:
(i) providing a first resistor;
(ii) providing a resistive network having a first terminal connected to said local voltage;
(iii) causing a first current substantially proportional to said voltage difference between said two master voltages to pass through said first resistor, and
(iv) causing a second current substantially proportional to a voltage across said first resistor to pass through said resistive network;
said local reference voltage then being present at a second terminal of said resistive network.

10. The method of claim 9, wherein said causing of said first current to pass through said first resistor is effected by steps including:
(A) providing a second resistor;
(B) providing a first field effect transistor;
(C) providing a second field effect transistor;
(D) providing a first negative feedback amplifier operative to drive said first field effect transistor so as to impress a voltage substantially equal to said first master reference voltage upon a first terminal of said second resistor, and
(E) providing a second negative feedback amplifier operative to drive said second field effect transistor so as to impress a voltage substantially equal to said second master reference voltage upon a second terminal of said second resistor;
said first current then flowing through said second resistor.

11. The method of claim 9, wherein said causing of said second current to pass through said resistive network is effected by steps including;
(A) providing a field effect transistor, and
(B) providing a negative feedback amplifier operative to drive said field effect transistor so as to cause said current substantially proportional to said voltage difference across said first resistor to flow through said resistive network.

12. The method of claim 8, wherein at least one of said providing of said first master reference voltage line and said providing of said second master reference voltage line is effected by steps including:
(i) providing at least two resistors configured as a voltage divider, and
(ii) using said voltage divider to impress a voltage proportional to a primary reference voltage upon a said master reference voltage line.

13. The method of claim 12, further comprising the steps of
(iii) providing a bandgap reference voltage source, and
(iv) obtaining said primary reference voltage from said bandgap reference voltage source.
